(19) United States
(12) Patent Application Publication
(10) Pub. No.: US 2026/0066014 A1
(43) Pub. Date: Mar. 5, 2026

(54) FLASH MEMORY DEVICE AND PROGRAMMING METHOD THEREOF

(71) Applicant: Winbond Electronics Corp., Taichung City (TW)

(72) Inventor: Chung-Zen Chen, HsinChu (TW)

(73) Assignee: Winbond Electronics Corp., Taichung City (TW)

(21) Appl. No.: 19/278,808

(22) Filed: Jul. 24, 2025

(30) Foreign Application Priority Data
Sep. 2, 2024 (TW) 113133101

(51) Int. Cl. G11C 16/34; G11C 16/10; G11C 16/32

(52) U.S. Cl. CPC G11C 16/3459; G11C 16/102; G11C 16/32

(57) ABSTRACT

A flash memory device and a programming method thereof are provided. The flash memory device includes a memory array and a memory control circuit. The memory array has a plurality of bit groups. The memory control circuit is configured to sequentially perform programming operations on the bit groups. The memory control circuit performs one or more programming verification cycles on a target bit group in the bit groups when the target bit group fails a programming verification, wherein the target bit group is divided into M parts, and M is a positive integer greater than 1. The memory control circuit determines whether the programming verification cycle performed on the target bit group is a first programming verification cycle. The memory control circuit sequentially programs the M parts with a first programming time when the first programming verification cycle is performed on the target bit group.

### CROSS-REFERENCE TO RELATED APPLICATION

This application claims the priority benefit of Taiwan application serial no. 113133101, filed on Sep. 2, 2024. The entirety of the above-mentioned patent application is hereby incorporated by reference herein and made a part of this specification.

### BACKGROUND

### Technical Field

The disclosure relates to a control technique of a memory device, and particularly relates to a flash memory device and a programming method thereof for reducing a programming current generated during a programming operation.

### Description of Related Art

Regarding a programming operation of a NOR flash memory device, in addition to a programming time, a programming current flowing from a drain to a source of a memory cell is also an important parameter that may be used to save power consumption. When programming a specific number of memory cells, a regulator with a charge pump circuit may be used to provide a stable drain voltage (for example, 4 volts) to the memory cells to generate programming currents, thus ensuring successful programming. However, an area occupied by the charge pump circuit may be directly proportional to a peak value of the programming currents generated by all of the memory cells during programming, which may also affect manufacturing cost of product. Therefore, how to reduce the programming current generated during the programming operation of the NOR flash memory device has become one of the important issues in this field.

### SUMMARY

The disclosure is directed to a flash memory device and a programming method thereof, which are adapted to dynamically adjust a number of bits (memory cells) to be programmed simultaneously and a programming time used in a programming verification cycle, thereby reducing a programming current generated when performing a programming operation.

The disclosure provides a flash memory device including a memory array and a memory control circuit. The memory array has a plurality of bit groups. The memory control circuit is coupled to the memory array, and is configured to sequentially perform a programming operation on the bit groups. The memory control circuit performs one or more programming verification cycles on a target bit group in the bit groups when the target bit group fails a programming verification, wherein the target bit group is divided into M parts, M is a positive integer greater than 1. The memory control circuit determines whether the programming verification cycle performed on the target bit group is a first programming verification cycle. The memory control circuit sequentially programs the M parts with a first programming time when the first programming verification cycle is performed on the target bit group.

The disclosure provides a programming method of a flash memory device including following steps: sequentially performing a programming operation on a plurality of bit groups; performing one or more programming verification cycles on a target bit group in the bit groups when the target bit group fails a programming verification, wherein the target bit group is divided into M parts, M is a positive integer greater than 1; determining whether the programming verification cycle performed on the target bit group is a first programming verification cycle; and sequentially programming the M parts with a first programming time when the first programming verification cycle is performed on the target bit group.

Based on the above description, the flash memory device and the programming method thereof of the disclosure may program only one part of the bit group at a time by using less programming time than conventionally programming when performing the first programming verification cycle on the target bit group, and proceed sequentially. In this way, a peak value of the programming current generated during the programming operation may be reduced, thereby reducing an area occupied by a charge pump circuit.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram of a flash memory device according to an embodiment of the disclosure.

FIG. 2, FIG. 3 and FIG. 4 step flowcharts of programming methods of the flash memory device according to some embodiments of the disclosure.

### DESCRIPTION OF THE EMBODIMENTS

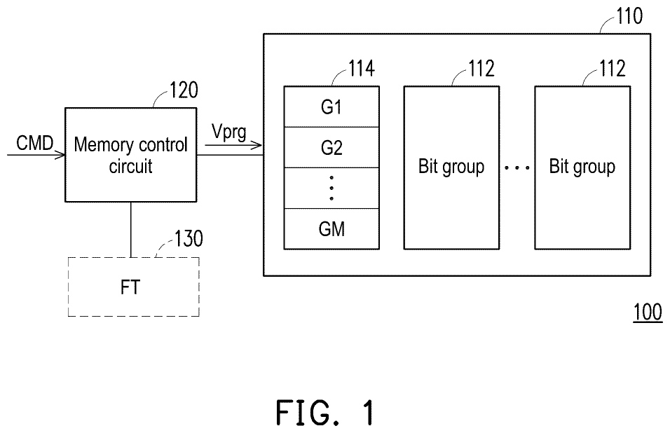

Referring to FIG. 1, a flash memory device 100 according to an embodiment of the disclosure is, for example, a NOR type and includes a memory array 110 and a memory control circuit 120. The memory array 110 includes a plurality of bit groups 112. Each bit group 112 is composed of a plurality of bits to be programmed into a specific data pattern. Structurally, one bit is equivalent to, for example, a memory cell with a memory tunneling oxide (ETOX) structure. It should be noted that the disclosure does not limit the number of the bit groups 112 and the number of bits (memory cells) that constitute one bit group 112.

The memory control circuit 120 is coupled to the memory array 110. The memory control circuit 120 may sequentially perform a programming operation on all of the bit groups 112. Specifically, the memory control circuit 120 may select a target bit group 114 from the plurality of bit groups 112 in the memory array 110 according to a received selection command CMD to perform the programming operation. In the embodiment, the target bit group 114 may be divided into M parts G1 to GM, where M is a positive integer greater than 1. For example, each of the parts G1-GM may include 16 bits. The part G1 includes the highest 16 bits in the target bit group 114, the part G2 includes 16 bits immediately following the bits of the part G1 in the target bit group 114, and so on. However, the disclosure does not limit the number of bits in each of the parts G1-GM, and those skilled in the art may make appropriate adjustments according to actual needs.

The memory control circuit 120 may be, for example, a state machine, a central processing unit, or other programmable general-purpose or special-purpose microprocessor, digital signal processor, programmable controller, special application integrated circuit, programmable logic device, or other similar devices or combinations of these devices, and may also be a hardware circuit designed through a hardware description language or any other conventional digital circuit design method, and implemented through a field programmable logic gate array or a complex programmable logic device, etc. In addition, although the memory control circuit 120 is shown in FIG. 1 as being located in the flash memory device 100, the memory control circuit 120 may also be a device independent to the flash memory device 100.

Optionally, the flash memory device 100 further includes a flag register 130. The flag register 130 is coupled to the memory control circuit 120, and is configured to store a times flag FT. Each time a programming verification cycle is executed, the memory control circuit 120 may set an initial value of the times flag FT to a first value (for example, “0”). Moreover, although the flag register 130 is shown in FIG. 1 as being independent to the memory array 110 and the memory control circuit 120, the flag register 130 may also be integrated into the memory array 110 or the memory control circuit 120.

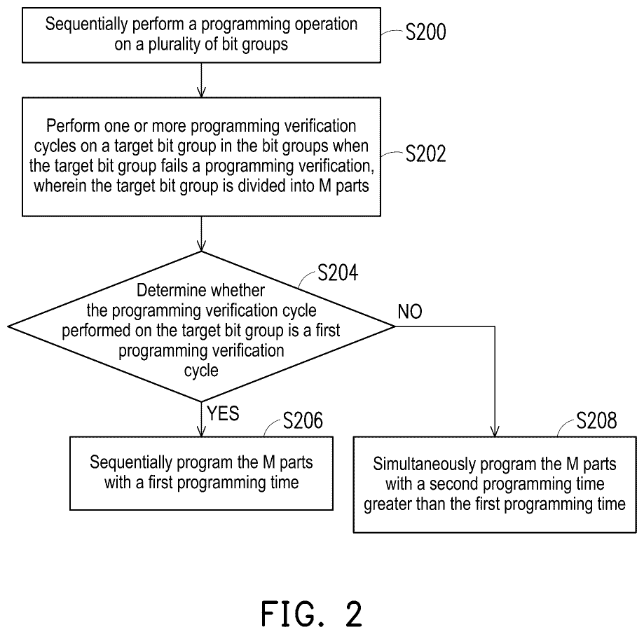

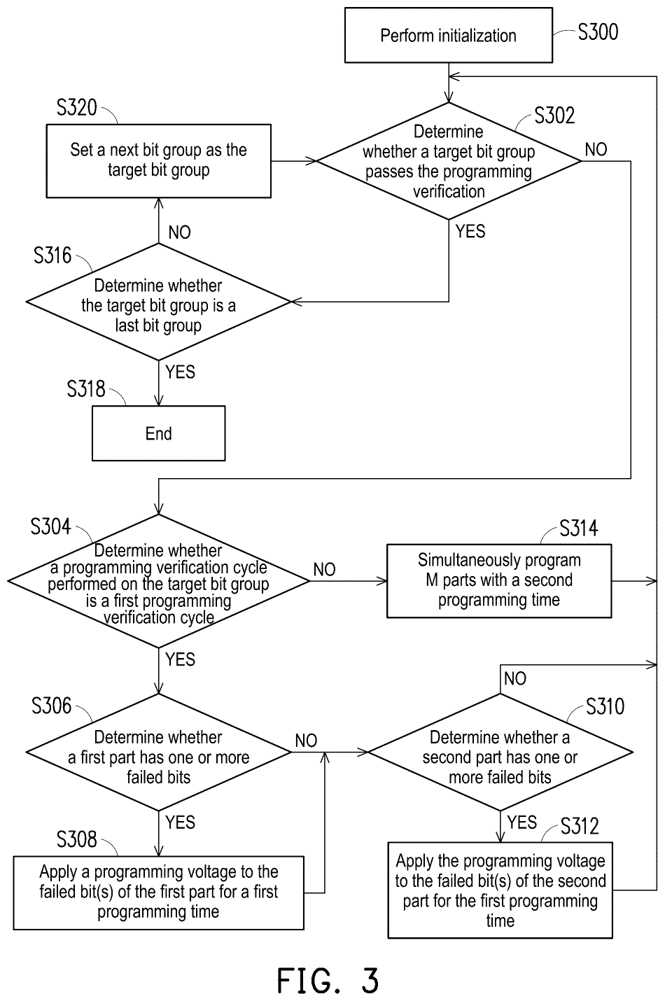

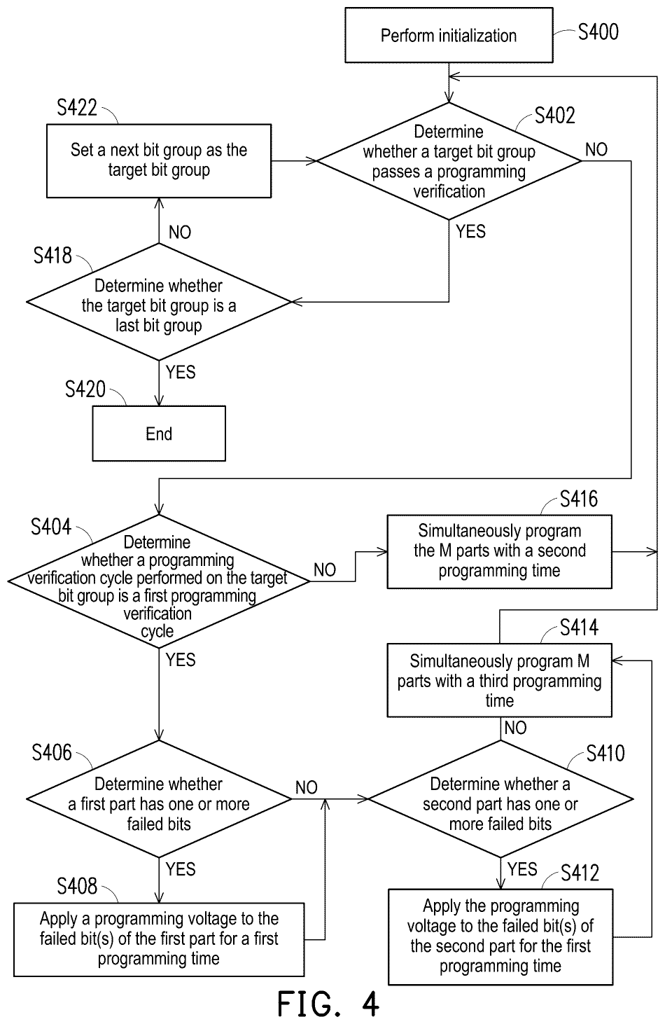

Referring to FIG. 1 and FIG. 2 at the same time, a programming method of the flash memory device of the embodiment is applicable to the flash memory device 100 of FIG. 1, and various steps of the programming method of the embodiment of the disclosure are described below with reference of various components of the flash memory device 100.

First, in step S200, the memory control circuit 120 sequentially performs a programming operation on the plurality of bit groups 112. For example, the memory control circuit 120 may perform initialization, and set one of the bit groups 112 to be programmed in the memory array 110 (for example, a first bit group) as the target bit group 114.

Then, the memory control circuit 120 may compare bit data (for example, 32 bits) formed by the target bit group 114 with a specific data pattern (for example, 32 bits) to determine whether the target bit group 114 passes programming verification. In more detail, in an example of programming verification, the memory control circuit 120 may determine whether a threshold voltage (Vth) of each bit (memory cell) in the target bit group 114 complies with a specified range of each bit value in the specific data pattern.

For example, if a bit value in a data pattern is “0”, a corresponding threshold voltage needs to be greater than a preset programming verification reference voltage, and if the bit value in the data pattern is “1”, the corresponding threshold voltage needs to be less than the preset programming verification reference voltage. The data patterns corresponding to each of the bit groups 112 may be the same or different.

Therefore, in step S202, if the target bit group 114 fails the programming verification, the memory control circuit 120 may perform one or more programming verification cycles on the target bit group 114.

Then, in step S204, the memory control circuit 120 determines whether the programming verification cycle executed on the target bit group 114 is a first programming verification cycle. When the first programming verification cycle is performed on the target bit group 114, in step S206, the memory control circuit 120 sequentially programs the M parts G1-GM of the target bit group 114 with a first programming time. For example, the memory control circuit 120 may set an initial value of K to 1, and the memory control circuit 120 may determine whether a K-th part GK of the target bit group 114 has one or more failed bits. If yes, the memory control circuit 120 applies a programming voltage Vprg to the failed bit(s) of the K-th part GK for the first programming time, and increments K (K=K+1) to continue determination of a next part. If not, the memory control circuit 120 directly increments K (K=K+1) to continue the determination of the next part. In the embodiment, the so-called “failed bit(s)” refer to bit(s) (memory cell(s)) within the target bit group 114 that have failed the programming verification. The programming voltage Vprg includes voltages applied to a gate node, a drain node, a source node and a well region of the failed bit, especially the voltage applied to the drain node. For example, the voltage applied to the gate node may be 9 volts, the voltage applied to the drain node may be 4 volts, and the voltage applied to the source node and the well region may be 0 volt, but the disclosure is not limited thereto.

In addition, the memory control circuit 120 may repeat the above-mentioned step of determining whether the K-th part GK has one or more failed bits and the step of incrementing K, thereby continuing to determine the next part until K is greater than M (all of the parts G1-GM have been determined).

On the other hand, when the programming verification cycle other than the first programming verification cycle (for example, the second programming verification cycle, the third programming verification cycle, etc.) is performed on the target bit group 114, in step S208, the memory control circuit 120 simultaneously programs the M parts G1-GM of the target bit group 114 with a second programming time that is greater than the first programming time. Specifically, the memory control circuit 120 may simultaneously apply the programming voltage Vprg to the failed bits of all of the M parts G1-GM for the second programming time. In practical applications, the first programming time is, for example, 0.2 microseconds, and the second programming time is, for example, 0.8 microseconds, which are both shorter than a conventional programming time (for example, 1 microsecond) used for the bit group of 32 bits.

By observing characteristics of the NOR flash memory device, a programming current generated by all of the bits (memory cells) during programming may decrease over time. In the embodiment, since the number of failed bits in the first programming verification cycle is the largest, the memory control circuit 120 only applies the programming voltage Vprg to the failed bits of one part GK of the target bit group 114 at a time for the first programming time in the first programming verification cycle, so as to reduce a peak value of the programming current generated by all of the failed bits that are simultaneously applied with the programming voltage Vprg.

Since the number of the failed bits in the programming verification cycles other than the first programming verification cycle may decrease as the number of the programming verification cycles increases, in the programming verification cycles other than the first programming verification cycle, the memory control circuit 120 may simultaneously apply the programming voltage Vprg to the failed bits of all of the M parts G1-GM of the target bit group 114 at a time for the second programming time, so as to improve a speed of programming verification. In this way, the time spent in programming operations may be reduced while taking into account the programming current.

The programming method of the disclosure will be described in more detail below with reference of the embodiment shown in FIG. 3. Referring to FIG. 1 and FIG. 3 at the same time, the programming method of the flash memory device of the embodiment is applicable to the flash memory device 100 of FIG. 1, and various steps of the programming method of the embodiment of the disclosure are described below with reference of various components of the flash memory device 100. In the embodiment, the parts that are the same or similar to the description of FIG. 2 will not be repeated. In addition, in order to simplify the description, in the embodiment, it is assumed that the target bit group 114 is divided into two parts G1 and G2 (M equals to 2).

First, in step S300, the memory control circuit 120 performs initialization and sets a first bit group among all of the bit groups 112 to be programmed in the memory array 110 as the target bit group 114.

Then, in step S302, the memory control circuit 120 determines whether the target bit group 114 passes the programming verification. When the target bit group 114 fails the programming verification, in step S304, the memory control circuit 120 determines whether the programming verification cycle performed on the target bit group 114 is the first programming verification cycle. To be specific, the memory control circuit 120 may determine whether the programming verification cycle performed on the current target bit group 114 is the first programming verification cycle according to the times flag FT.

When the times flag FT is a first value (for example, “0”), the memory control circuit 120 may determine that the programming verification cycle performed on the current target bit group 114 is the first programming verification cycle, and in step S306, the memory control circuit 120 determines whether a first part G1 of the target bit group 114 has one or more failed bits. If yes, in step S308, the memory control circuit 120 applies the programming voltage Vprg to the failed bit(s) of the first part G1 for the first programming time, and then the method flow proceeds to S310. If not, the method flow proceeds directly to S310 after step S306.

In step S310, the memory control circuit 120 determines whether a second part G2 of the target bit group 114 has one or more failed bits. If yes, in step S312, the memory control circuit 120 applies the programming voltage Vprg to the failed bit(s) of the second part G2 for the first programming time, and then the memory control circuit 120 sets the times flag FT to a second value (for example, “1”), and the method flow returns to step S302 to continue the second programming verification cycle. If not, after step S310, the memory control circuit 120 sets the times flag FT to the second value, and the method flow returns to step S302.

In step S304, when the memory control circuit 120 determines that the times flag FT stored in the flag register 130 is not the first value (but is the second value), the memory control circuit 120 may determine that the programming verification cycle performed on the current target bit group 114 is a programming verification cycle other than the first programming verification cycle (for example, the second programming verification cycle, the third programming verification cycle, etc.), and in step S314, the memory control circuit 120 simultaneously programs the two parts G1 and G2 of the target bit group 114 with the second programming time greater than the first programming time. Specifically, the memory control circuit 120 may simultaneously apply the programming voltage Vprg to the failed bits of all of the two parts G1 and G2 for the second programming time, and then the method flow returns to step S302 to continue a next programming verification cycle.

On the other hand, when the memory control circuit 120 determines that the target bit group 114 passes the programming verification in step S302, in step S316, the memory control circuit 120 determines whether the target bit group 114 is a last bit group among all of the bit groups 112 to be programmed. If yes, the method flow proceeds to S318 to end the programming operation of the memory array 110. If not, in step S320, the memory control circuit 120 sets a next bit group in the bit groups 112 as the target bit group 114, and then the method flow proceeds to S302 to continue the programming operation.

Another embodiment is provided below to illustrate the programming method of the disclosure. Referring to FIG. 1 and FIG. 4 at the same time, the programming method of the flash memory device of the embodiment is applicable to the flash memory device 100 of FIG. 1, and various steps of the programming method of the embodiment of the disclosure are described below with reference of various components of the flash memory device 100. In the embodiment, the same or similar parts as those in the description of FIG. 2 and FIG. 3 will not be repeated. Similarly, in the embodiment, it is assumed that the target bit group 114 is divided into two parts G1 and G2 (M equals to 2).

First, in step S400, the memory control circuit 120 performs initialization and sets the first bit group among all of the bit groups 112 to be programmed in the memory array 110 as the target bit group 114.

Then, in step S402, the memory control circuit 120 determines whether the target bit group 114 passes the programming verification. When the target bit group 114 fails the programming verification, in step S404, the memory control circuit 120 determines whether the programming verification cycle performed on the target bit group 114 is the first programming verification cycle.

When the memory control circuit 120 determines that the programming verification cycle performed on the current target bit group 114 is the first programming verification cycle, in step S406, the memory control circuit 120 determines whether the first part G1 of the target bit group 114 has one or more failed bits. If yes, in step S408, the memory control circuit 120 applies the programming voltage Vprg to the failed bit(s) of the first part G1 for the first programming time, and then the method flow proceeds to S410. If not, the method flow proceeds directly to S410 after step S406.

In step S410, the memory control circuit 120 determines whether the second part G2 of the target bit group 114 has one or more failed bits. If yes, in step S412, the memory control circuit 120 applies the programming voltage Vprg to the failed bit(s) of the second part G2 for the first programming time, and then the method flow proceeds to S414. If not, the method flow proceeds directly to S414 after step S410.

Different from the previous embodiment, after determining whether the second part G2 of the target bit group 114 has one or more failed bits, in step S414, the memory control circuit 120 simultaneously programs the two parts G1 and G2 of the target bit group 114 with a third programming time. The third programming time in the embodiment is, for example, greater than the first programming time and less than or equal to the second programming time. Specifically, the memory control circuit 120 may simultaneously apply the programming voltage Vprg to the failed bits of all of the two parts G1 and G2 for the third programming time. Then, the method flow returns to step S402 to continue a next programming verification cycle.

In step S404, when the memory control circuit 120 determines that the programming verification cycle performed on the current target bit group 114 is a programming verification cycle other than the first programming verification cycle (such as the second programming verification cycle, the third programming verification cycle, etc.), in step S416, the memory control circuit 120 simultaneously programs the two parts G1 and G2 of the target bit group 114 with the second programming time that is greater than the first programming time.

On the other hand, when the memory control circuit 120 determines that the target bit group 114 passes the programming verification in step S402, in step S418, the memory control circuit 120 determines whether the target bit group 114 is the last bit group among all of the bit groups 112 to be programmed. If yes, the method flow then proceeds to S420 to end the programming operation of the memory array 110. If not, in step S422, the memory control circuit 120 sets a next bit group in the bit groups 112 as the target bit group 114, and then the method flow proceeds to S402 to continue the programming operation.

In summary, the flash memory device and the programming method thereof of the disclosure may reduce the programming currents generated during programming operations. Even though the total programming time may increase a little, the peak value of the generated programming currents will be greatly reduced, which may greatly reduce the area occupied by the charge pump circuit and reduce the manufacturing cost of product, which is beneficial to applications of the Internet of Things (IOT) and batteries. Therefore, the disclosure provides a green semiconductor technology.

What is claimed is:

1. A flash memory device, comprising:
a memory array, having a plurality of bit groups; and
a memory control circuit, coupled to the memory array, and configured to sequentially perform a programming operation on the bit groups,
wherein the memory control circuit performs one or more programming verification cycles on a target bit group in the bit groups when the target bit group fails a programming verification;
the target bit group is divided into M parts, and M is a positive integer greater than 1;
the memory control circuit determines whether the programming verification cycle performed on the target bit group is a first programming verification cycle, the memory control circuit sequentially programs the M parts with a first programming time when the first programming verification cycle is performed on the target bit group; and
the memory control circuit simultaneously programs the M parts with a second programming time greater than the first programming time when the programming verification cycle other than the first programming verification cycle is performed on the target bit group.

2. The flash memory device as claimed in claim 1, wherein when performing the first programming verification cycle on the target bit group, the memory control circuit sets an initial value of K to 1, and determines whether a K-th part of the target bit group has one or more failed bits, and if yes, the memory control circuit applies a programming voltage to the one or more failed bits of the K-th part for the first programming time.

3. The flash memory device as claimed in claim 2, wherein the memory control circuit increments K to continue determining a next part, and repeats the step of determining whether the K-th part has the one or more failed bits and the step of incrementing K until K is greater than M.

4. The flash memory device as claimed in claim 3, wherein after determining whether an M-th part of the target bit group has the one or more failed bits, the memory control circuit simultaneously programs the M parts with a third programming time, wherein the third programming time is greater than the first programming time and less than or equal to the second programming time.

5. The flash memory device as claimed in claim 1, wherein the flash memory device further comprises a flag register configured to store a times flag, the flag register is coupled to the memory control circuit, and the memory control circuit determines whether the programming verification cycle performed on the target bit group is the first programming verification cycle according to the times flag.

6. The flash memory device as claimed in claim 5, wherein the flag register is independent to the memory array and the memory control circuit.

7. The flash memory device as claimed in claim 5, wherein the flag register is integrated into the memory array or the memory control circuit.

8. The flash memory device as claimed in claim 1, wherein when the target bit group passes the programming verification, the memory control circuit determines whether the target bit group is a last bit group, and if not, the memory control circuit sets a next bit group as the target bit group to perform the programming operation.

9. A programming method of a flash memory device, wherein the flash memory device comprises a memory array with a plurality of bit groups, and the programming method comprises:
sequentially performing a programming operation on the bit groups;
performing one or more programming verification cycles on a target bit group in the bit groups when the target bit group fails a programming verification, wherein the target bit group is divided into M parts, and M is a positive integer greater than 1;
determining whether the programming verification cycle performed on the target bit group is a first programming verification cycle;
sequentially programming the M parts with a first programming time when the first programming verification cycle is performed on the target bit group; and
simultaneously programming the M parts with a second programming time greater than the first programming time when the programming verification cycle other than the first programming verification cycle is performed on the target bit group.

10. The programming method as claimed in claim 9, wherein the step of sequentially programming the M parts with the first programming time comprises:
setting an initial value of K to 1;
determining whether a K-th part of the target bit group has one or more failed bits; and
if yes, applying a programming voltage to the one or more failed bits of the K-th part for the first programming time.

11. The programming method as claimed in claim 10, wherein the step of sequentially programming the M parts with the first programming time further comprises:
incrementing K to continue determining a next part; and
repeating the step of determining whether the K-th part has the one or more failed bits and the step of incrementing K until K is greater than M.

12. The programming method as claimed in claim 11, further comprising:
after determining whether an M-th part of the target bit group has the one or more failed bits, simultaneously programming the M parts with a third programming time, wherein the third programming time is greater than the first programming time and less than or equal to the second programming time.

13. The programming method as claimed in claim 9, wherein the flash memory device further comprises a flag register configured to store a times flag, and the step of determining whether the programming verification cycle performed on the target bit group is the first programming verification cycle comprises:
determining whether the programming verification cycle performed on the target bit group is the first programming verification cycle according to the times flag.

14. The programming method as claimed in claim 9, further comprising:
determining whether the target bit group is a last bit group when the target bit group passes the programming verification; and
if not, setting a next bit group as the target bit group to perform the programming operation.
